(19) United States
(12) Patent Application Publication
(10) Pub. No.: US 2007/0231752 A1
(43) Pub. Date: Oct. 4, 2007

(54) Method for Shrinking Opening Sizes of a Photoresist Pattern

(75) Inventor: Yee-Kai Lai, Jungli City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: PROMOS TECHNOLOGIES, INC., Hsinchu (TW)

(21) Appl. No.: 11/464,304

(22) Filed: Aug. 14, 2006

(30) Foreign Application Priority Data
Apr. 3, 2006 (TW) 95111833

(51) Int. Cl. G03F 7/26

(52) U.S. Cl. 430/330; 430/322; 430/324

(57) ABSTRACT

A method for shrinking opening sizes of a photoresist is provided. A patterned photoresist layer having an opening is formed on a substrate. The opening includes a first size. The photoresist layer is baked at a temperature below a glass transition temperature of the photoresist layer. A layer of SAFIER material is formed on the photoresist layer and the substrate. The layer of SAFIER material and the photoresist layer are baked at a temperature higher than the glass transition temperature to shrink the size of the opening. The layer of SAFIER material is removed. The first size of the opening is thus shrunk to a second size.

### RELATED APPLICATIONS

The present application is based on, and claims priority from, Taiwan Application Serial Number 95111833, filed Apr. 3, 2006, the disclosure of which is hereby incorporated by reference herein in its entirety.

### BACKGROUND

1. Field of Invention

The present invention relates to a shrinking method. More particularly, the present invention relates to a SAFIER (Shrink Assist Film for Enhanced Resolution) shrinking method.

2. Description of Related Art

With the growing development of integrated circuit, integrity of integrated circuit is increased and technique of shrinking device size becomes more and more important. Especially, critical dimensions of devices have to be shrunk to fabricate more transistors on one single wafer when semiconductor technology is upgraded to 90 nm or smaller generation. The critical dimensions of devices are determined by photolithography processes. That is, the photolithography process is a critical process to check whether the integrity of a metal-oxide semiconductor on a wafer is developed to smaller generation or smaller line width.

A thermal flow process is one of shrinking process to shrink contact hole or via hole, in which a traditional photolithography is first performed to form a patterned photoresist layer on a substrate and then a thermal flow process is performed to shrink opening sizes of the patterned photoresist layer. An etching process is performed to pattern films on the substrate to form a contact hole or via hole in the films. FIGS. 1A and 1B are cross-section schematic diagrams illustrating a traditional structure after performing a thermal flow process. In FIG. 1A, a patterned photoresist layer 102 having an opening 104 is formed on a substrate 100. In FIG. 1B, a thermal flow process is performed to shrink the opening 104 of the patterned photoresist layer 102 to obtain an opening 104a with smaller width. After that, an etching process is performed to form a contact hole or via hole in the films on the substrate. However, the problems of the thermal flow process used to shrink the contact hole or via hole is that the patterned photoresist layer 102 might generate an overhang at the sidewalls 106 of the opening 104a and the accuracy of following etching process is thus decreased. Moreover, as the result of optical proximity effect, each opening in width is different after performing the photolithography process in the contact hole or via hole having different pitch by using the same mask. The term “pitch” means that distances between each hole. Therefore, after the thermal flow process is used to shrink the opening, difference of the openings in width between isolated hole having greater pitch and dense hole having smaller pitch would be further worsened. The shrinking range of the isolated hole is usually greater than the dense hole.

Thus, a shrinking process, shrink assist film for enhanced resolution (SAFIER) was developed by Tokyo Ohka Kogyo company to solve these problems. In this process, a layer of SAFIER material is first coated on the patterned photoresist layer and then baked to shrink the opening sizes. The shrunk isolated hole in width is approximately the shrunk dense hole in width by using the SAFIRE process to shrink the contact hole or via hole having different pitch. However, the difficulty of the SAFIRE process is that shrinking range of the opening is limited. The maximum shrinking range of the opening is about 20 nm. Therefore, smaller opening size cannot be further obtained.

### SUMMARY

In one aspect, this present invention provides a method of shrinking opening sizes of the photoresist pattern to enhance shrinking effect.

In another aspect, this present invention provides a method of shrinking opening sizes of the photoresist pattern to minimize opening size difference for holes at different pitch.

In accordance with the foregoing and other aspects of the present invention, the present invention provides a method of shrinking opening sizes of the photoresist pattern comprising following steps. First, a patterned photoresist layer having at least an opening is formed on a substrate. The opening comprises a first width. The patterned photoresist layer is baked at a first temperature below a glass transition temperature of the patterned photoresist layer. The baking process mentioned above is preferably performing baking gradation processes from a lower temperature to a higher temperature below the glass transition temperature. A plurality of baking/cooling gradation processes is performed and the temperature for each of the baking gradation processes is higher than the temperature used in the preceding baking process thereof. Alternatively, the baking process may comprise a baking at one single temperature close to but below the glass transition temperature. Then, an enhanced shrinking layer is coated on the patterned photoresist layer and the substrate, and the opening is filled. The enhanced shrinking layer and the patterned photoresist layer are baked at a second temperature higher than the glass transition temperature. After that, the enhanced shrinking layer is removed. Therefore, the first width of the opening is reduced to a second width.

Thus, the present invention not only enhances shrinking effect of the photoresist pattern, but also solves problems of different opening sizes for holes at different pitch.

### BRIEF DESCRIPTION OF THE DRAWINGS

The invention can be more fully understood by reading the following detailed description of the preferred embodiment, with reference made to the accompanying drawings as follows:

FIGS. 1A and 1B are cross-section schematic diagrams illustrating a traditional structure after performing a thermal flow process.

FIG. 2A to 2F are cross-sectional diagrams illustrating a contact hole formed on a substrate according to one embodiment of the present invention.

FIG. 3 is a process flow diagram illustrating a SAFIER shrinking process according to one embodiment of the present invention.

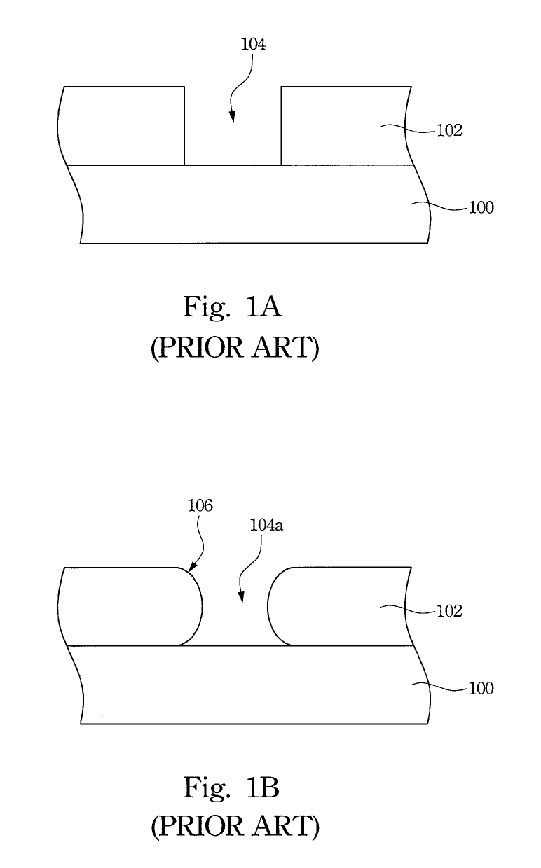

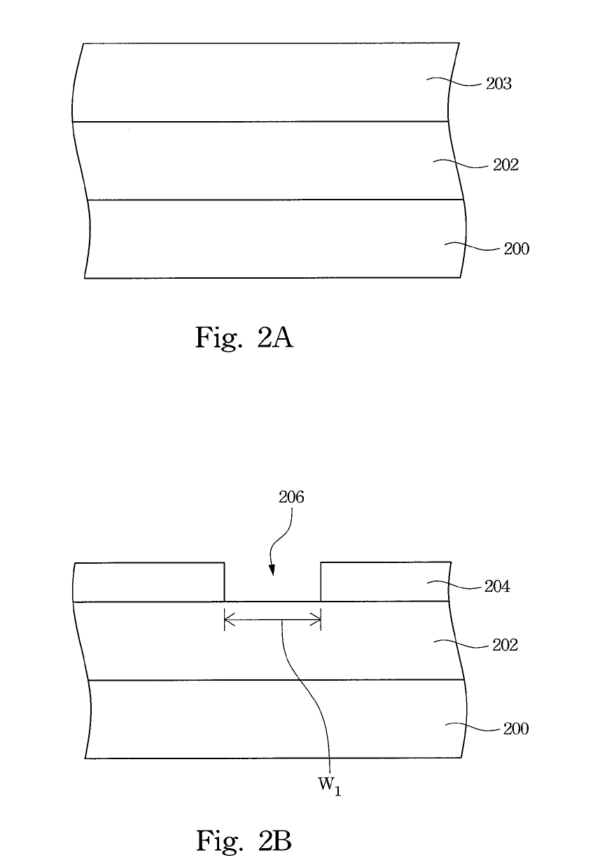

### DESCRIPTION OF THE PREFERRED EMBODIMENTS

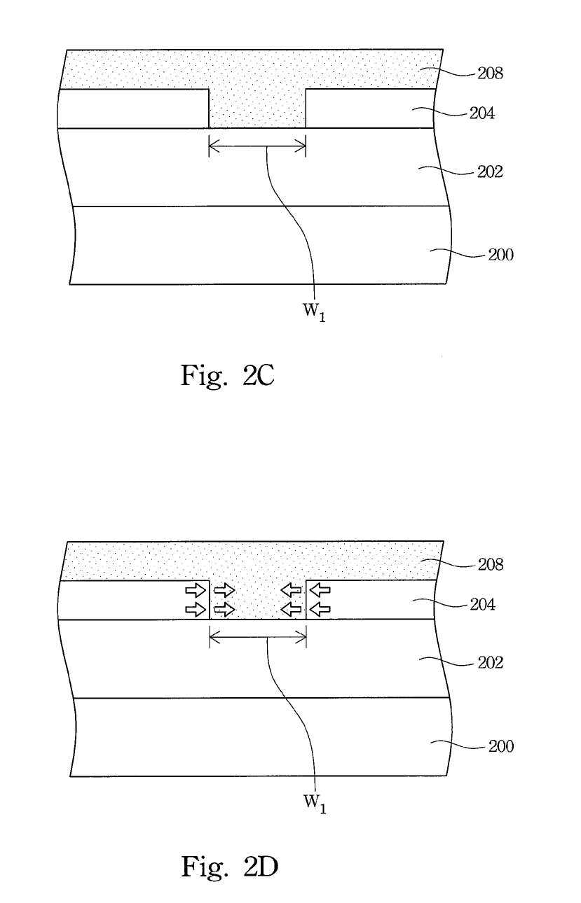

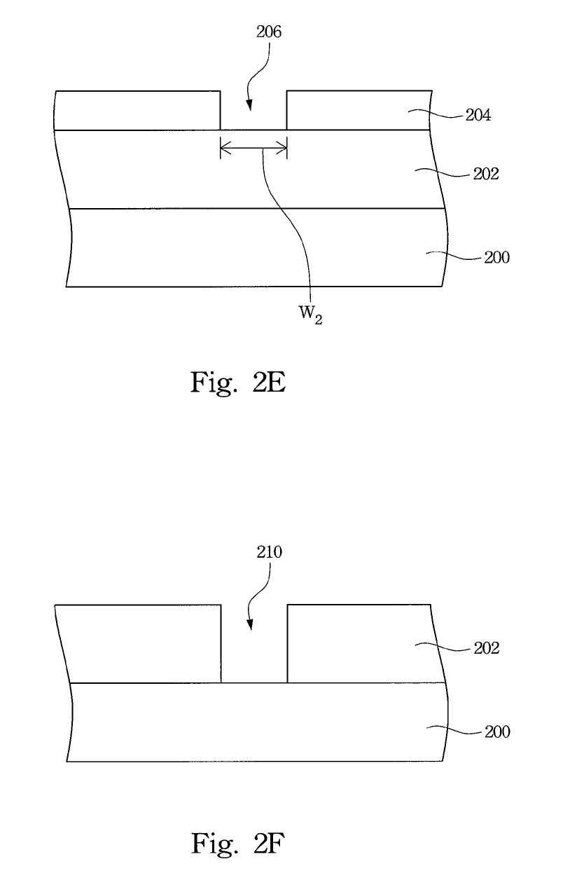

FIG. 2A to 2F are cross-sectional diagrams illustrating a contact hole formed on a substrate according to one embodiment of the present invention. In FIG. 2A, films, such as dielectric layer 202 and photoresist layer 203, are sequentially formed on a substrate 200. In FIG. 2B, a photolithography process is performed on the photoresist layer 203 to form a patterned photoresist layer 204 on the dielectric layer 202. The patterned photoresist layer 204 comprises an opening 206 having a first width W₁. The photolithography process comprises soft baking process, exposure process, post exposure baking process, and development process in sequence.

Then, the patterned photoresist layer 204 is baked at a first temperature below a glass transition temperature of the patterned photoresist layer 204. The baking process mentioned above is preferably performing baking gradation processes from a lower temperature to a higher temperature below the glass transition temperature. A plurality of baking/cooling gradation processes is performed and the temperature of each baking gradation processes is higher than the temperature used in the preceding baking process. Alternatively, the baking process may comprise a baking at one single temperature close to but below the glass transition temperature. The method of baking process is not used to limit to the scope of the present invention. According to the preferred embodiment of the present invention, the baking process is preferably performed by two baking/cooling gradation processes, a first baking gradation process and a second baking gradation process. The temperature of the first baking gradation process is below the glass transition temperature and the temperature of the second baking gradation process is closer to the glass transition temperature than the first baking temperature but still below the glass transition temperature.

In FIG. 2C, an enhanced shrinking layer, such as a layer of SAFIER material 208, is coated on the patterned photoresist layer 204 and the dielectric layer 202, and thus the opening 206 is filled. In FIG. 2D, the layer of SAFIER material 208 and the patterned photoresist layer 204 is baked at a second temperature over the glass transition temperature to shrink the first width W₁ of opening 206 of the patterned photoresist layer 204.

In. FIG. 2E, the layer of SAFIER material 208 is removed. According to one embodiment of the present invention, a deionized water is used to remove the layer of SAFIER material 208. The first width W₁ of the opening 206 is shrunk into a second width W₂. According to one embodiment of the present invention, the width of a contact hole which is about 140 nm before shrinking process can be shrunk over 50 nm, more preferably about 80 nm by performing the method of the present invention.

Finally, the shrunk patterned photoresist layer 204 is used as a mask and then the exposed dielectric layer 202 is etched to form a contact hole 210 in the dielectric layer 202 shown in FIG. 2F.

Therefore, before the layer of SAFIER material is coated on the patterned photoresist layer, the patterned photoresist layer is baked first, and then the layer of SAFIER material and the patterned photoresist layer are baked at the temperature below the glass transition temperature. At this temperature, the patterned photoresist layer is softened into flowable condition, so that the binding strength between the layer of SAFIER material and the patterned photoresist layer can be enhanced. Therefore, a greater pulling force enforces on the surface of the patterned photoresist layer while the layer of SAFIER material is shrunk. Moreover, the photoresist layer at temperatures over glass transition temperature can be easily deformed, so that the opening sizes can be shrunk further to enhance the shrinking effect of the photoresist pattern.

Furthermore, the method of the present invention increases the shrinking effect of the photoresist pattern and solves problem of different opening size for contact holes at different pitch after baking. The width difference between the isolated hole and the dense hole produced by foregoing method is reduced and thereby correction of the mask using an optical proximity correction can be reduced

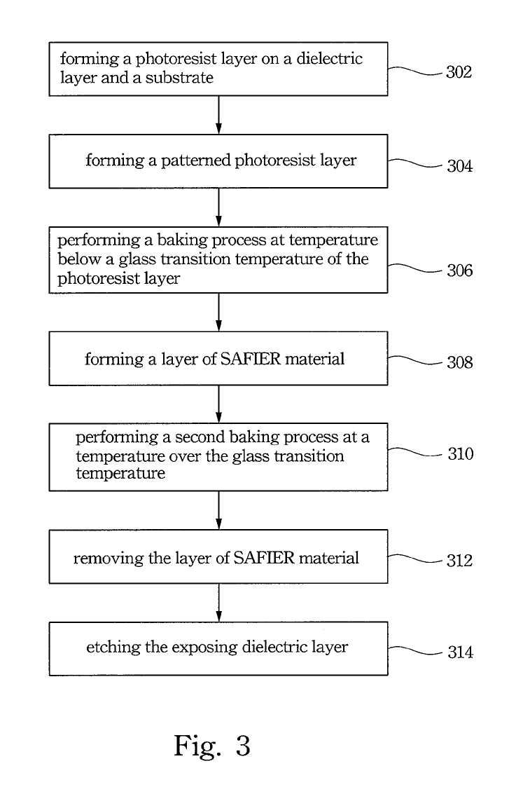

FIG. 3 is a process flow diagram illustrating a SAFIER shrinking process according to one embodiment of the present invention (referring to FIG. 2A˜2F). In step 302, a photoresist layer is formed on a dielectric layer and a substrate. In Step 304, a photolithography process is performed to form a patterned photoresist layer. In step 306, a baking process is performed at temperature below a glass transition temperature of the photoresist layer. The baking process mentioned above is preferably performing baking gradation processes from a lower temperature to a higher temperature below the glass transition temperature; then, performing a plurality of baking/cooling gradation processes and the temperature of each baking gradation processes is higher than the preceding baking process. Alternatively, the baking process may comprise a baking at a single temperature close to but below the glass transition temperature according to the demands. In step 308, an enhanced shrinking layer, such as a layer of SAFIER material, is formed on the patterned photoresist layer and the substrate. In step 310, a second baking process is performed at a temperature over the glass transition temperature to bake the enhanced shrinking layer and the patterned photoresist layer. In step 312, the layer of SAFIER material is removed. In step 314, the exposed dielectric layer is etched to form a contact hole.

Thus, the present invention provides a method for shrinking opening sizes of a photoresist pattern that can enhance shrinking effect of the photoresist pattern. Moreover, the present invention not only enhances shrinking effect of the photoresist pattern, but also solves problem of different opening sizes for holes at different pitch.

The preferred embodiments of the present invention described above should not be regarded as limitations to the present invention. It will be apparent to those skilled in the art that various modifications and variations can be made to the present invention without departing from the scope or spirit of the invention. The scope of the present invention is as defined in the appended claims.

What is claimed is:

1. A method of shrinking opening sizes of a photoresist pattern, the method comprising:
forming a patterned photoresist layer having at least an opening on a substrate;
baking the patterned photoresist layer at a first temperature below a glass transition temperature of the patterned photoresist layer;
coating an enhanced shrinking layer on the patterned photoresist layer and the substrate to fill the opening;
baking the enhanced shrinking layer and the patterned photoresist layer at a second temperature higher than the glass transition temperature; and
removing the enhanced shrinking layer.

2. The method of shrinking opening sizes of a photoresist pattern of claim 1, wherein the step of baking the patterned photoresist layer at the first temperature below the glass transition temperature further comprises performing baking gradation processes at a lower temperature below the glass transition temperature.

3. The method of shrinking opening sizes of a photoresist pattern of claim 1, wherein the step of baking the patterned photoresist layer at the first temperature below the glass transition temperature further comprises performing a plurality of baking/cooling gradation processes to bake the patterned photoresist layer.

4. The method of shrinking opening sizes of a photoresist pattern of claim 3, wherein the temperature for each of the baking processes is higher than the temperature of its preceding baking process.

5. The method of shrinking opening sizes of a photoresist pattern of claim 3, wherein the step of baking the patterned photoresist layer at the first temperature below the glass transition temperature further comprises a first baking gradation and a second baking gradation, wherein temperature of the first baking gradation is below the glass transition temperature and temperature of the second baking gradation is close to but below the glass transition temperature.

6. The method of shrinking opening sizes of a photoresist pattern of claim 1, wherein the step of baking the patterned photoresist layer at the first temperature below the glass transition temperature further comprises performing a baking process at a single temperature close to but below the glass transition temperature.

7. The method of shrinking opening sizes of a photoresist pattern of claim 1, wherein the opening is shrunk more than 50 nm in width.

8. The method of shrinking opening sizes of a photoresist pattern of claim 1, wherein the step of removing the enhanced shrinking layer comprises using deionized water.

9. A method of forming a hole, the method comprising:
forming a dielectric layer on a substate;
forming a patterned photoresist layer having at least an opening on the dielectric layer;
baking the patterned photoresist layer at a first temperature below a glass transition temperature of the patterned photoresist layer;
coating an enhanced shrinking layer on the patterned photoresist layer and the substrate to fill the opening;
baking the enhanced shrinking layer and the patterned photoresist layer at a second temperature over the glass transition temperature to shrink the opening in width;
removing the enhanced shrinking layer; and
etching the exposed dielectric layer to form at least a hole.

10. The method of shrinking opening sizes of a photoresist pattern of claim 9, wherein the step of baking the patterned photoresist layer at the first temperature below the glass transition temperature further comprises performing baking gradation processes at a low temperature to below the glass transition temperature.

11. The method of shrinking opening sizes of a photoresist pattern of claim 9, wherein the step of baking the patterned photoresist layer at the first temperature below the glass transition temperature further comprises performing a plurality of baking/cooling gradation processes to bake the patterned photoresist layer.

12. The method of shrinking opening sizes of a photoresist pattern of claim 11, wherein the temperature for each of baking processes is higher than the temperature of its baking process.

13. The method of shrinking opening sizes of a photoresist pattern of claim 11, wherein the step of baking the patterned photoresist layer at the first temperature below the glass transition temperature further comprises a first baking gradation and a second baking gradation, wherein temperature of the first baking gradation is below the glass transition temperature and temperature of the second baking gradation is close to but below the glass transition temperature.

14. The method of shrinking opening sizes of a photoresist pattern of claim 9, wherein the step of baking the patterned photoresist layer at the first temperature below the glass transition temperature further comprises performing a baking process at a single temperature close to but below the glass transition temperature.

15. The method of shrinking opening sizes of a photoresist pattern of claim 9, wherein the opening is shrunk more than 50 nm in width.

16. The method of shrinking opening sizes of a photoresist pattern of claim 9, wherein the step of removing the enhanced shrinking layer comprises using deionized water.
